(19) United States
(12) Patent Application Publication
(10) Pub. No.: US 2004/0237880 A1
(43) Pub. Date: Dec. 2, 2004

(54) Method for manufacturing an optical member formed of a fluoride crystal

(75) Inventors: Shigeru Sakuma, Chigasaki (JP); Kenichi Muramatsu, Sagamihara (JP); Kazuhiro Kido, Sagamihara (JP)

Correspondence Address: OLIFF & BERRIDGE, PLC, P.O. BOX 19928, ALEXANDRIA, VA, 22320, US

(73) Assignee: Nikon Corporation, Tokyo (JP)

(21) Appl. No.: 10/673,393

(22) Filed: Sep. 30, 2003

(30) Foreign Application Priority Data
Oct. 1, 2002 (JP) 2002-288234

(51) Int. Cl. C30B 15/00; C30B 21/06; C30B 27/02; C30B 30/04; C30B 28/10

(52) U.S. Cl. 117/13

(57) ABSTRACT

A method for manufacturing an optical member of a fluoride crystal includes: a growing step of growing an ingot of a fluoride crystal; a cutting-out step of cutting out from the ingot a cylindrical basic material with two parallel planes which have a certain crystal plane orientation; an orientation-determining step of determining a crystal orientation of a side surface of the cylindrical basic material; a birefringence-measuring step of measuring birefringence in a specific crystal axis direction at the side surface determined based on the crystal orientation determined in the orientation-determining step; and an evaluating step of evaluating the fluoride crystal on the basis of a result of measurement of the birefringence. A fluoride crystal is obtained in which a maximum value of birefringence in a specific crystal axis direction at a side surface is not more than 10 nm/cm at a measurement wavelength of 633 nm. A high-resolution lens suitable for an oblique incident beam and an exposure apparatus using the lens are provided.

### BACKGROUND OF THE INVENTION

1. Field of the Invention

The present invention relates to a manufacturing method for manufacturing an optical member for constituting an optical system in an optical apparatus such as a camera, a microscope, or a telescope and an photolithography apparatus such as a stepper as well as an optical element thereby obtained, and more particularly to an optical member formed of a fluoride crystal used as an optical member for photolithography of not more than 250 nm as well as a method for manufacturing the same.

2. Description of the Related Art

In recent years, rapid development is being made in lithography technology for depicting integrated circuit patterns on wafers. There has been ever-increasing demand for higher integration of integrated circuits, and in order to realize the higher integration it is necessary to increase the resolution of a projection optical system of a projection exposure apparatus. The resolution of a projection lens is governed by the wavelength of the light used and the numerical aperture (NA) of the projection lens. In order to increase the resolution, it suffices if the wavelength of the light used is made shorter and NA of the projection lens is made larger (larger aperture).

First, a description will be given of the trend toward the shorter wavelength of the light. As for the wavelengths of light sources used in projection exposure apparatuses, the trend toward the shorter wavelength is underway from g-line (wavelength: 436 nm ) to i-line (wavelength: 365 nm ), and further from KrF excimer laser light (wavelength: 248 nm ) to ArF excimer laser light (wavelength: 193 nm ). If F₂ laser light (wavelength: 157 nm ) or the like whose wavelength is still shorter is to be used in the future, it is no longer possible to use general optical glass as a lens material of an image-forming optical system such as a projection optical system since a decline in transmittance presents a problem.

For this reason, as the optical system of an F₂ laser stepper, it is considered commonplace to use a fluoride crystal, e.g., calcium fluoride (fluorite), as the optical member.

Next, a description will be given of the trend toward the larger aperture. In order to satisfy the optical performance as an optical member for use in the optical system of the KrF, ArF excimer laser stepper or the F₂ laser stepper, it is considered the crystal material is preferably a single crystal.

In addition, in conjunction with the trend toward the high performance of the projection exposure apparatus, a large-diameter calcium fluoride single crystal having a diameter of φ100 mm to φ350 mm or thereabouts has recently come to be required. Because of its low refractive index and small dispersion (wavelength dependence of the refractive index) as compared with general optical glass, such a calcium fluoride (fluorite) single crystal is very effective in that chromatic aberrations can be corrected when used together with an optical member formed of another material. In addition, as compared with the other crystal materials (barium fluoride), the calcium fluoride (fluorite) single crystal is easily available from the market, and large-diameter single crystals with diameters of φ100 mm or more are available.

The calcium fluoride single crystals having these advantages have conventionally been used as a lens material for cameras, microscopes, and telescopes in addition to an optical material for steppers. In addition, single crystals of barium fluoride and strontium fluoride, which are fluoride single crystals other than the calcium fluoride single crystal, have recently attracted attention as a next-generation optical material in view of the fact that these single crystals belong to the same isometric system and their properties are similar.

As for the fluoride single crystals, single-crystal growing methods are known including melting methods such as the Bridgman method (Stockbarger or lowering method) and the Tammann method.

One example of the method of manufacturing a calcium fluoride single crystal in accordance with the Bridgman method is shown below.

In the case of the calcium fluoride single crystal used in ultraviolet to vacuum ultraviolet regions, natural fluorite is not used as the material, and a high-purity material manufactured by chemical synthesis is generally used.

The material can be used in powder form, in which case the reduction in volume is intense when it is melted, so that a semi-molten product or a pulverized product thereof is generally used. First, a crucible with the material filled therein is placed in a growing apparatus, and the interior of the growing apparatus is kept in a vacuum atmosphere of 10⁻³ to 10⁻⁴ Pa. Then, the temperature within the growing apparatus is increased to a level above the melting point of calcium fluoride (1370° C. to 1450 ° C.) to melt the material. At this time, control based on constant power output or high-precision PID control is effected so as to suppress the temporal change of the temperature within the growing apparatus.

At the stage of crystal growth, the crucible is lowered at a speed of 0.1 to 5 mm/h or thereabouts, thereby allowing the material to gradually crystallize starting with a lower portion in the crucible. When crystallization has occurred up to an uppermost portion of the melt, crystal growth is completed, and simple annealing is effected by avoiding quenching so that the grown crystal (ingot) will not fracture. When the temperature within the growing apparatus has lowered to room temperature or thereabouts, the apparatus is opened to atmosphere, and the ingot is removed.

In this crystal growth, a graphite-made crucible is normally used. As for its shape, the graphite-made crucible is of a pencil type whose tip portion is conical and whose remaining portion is cylindrical. By allowing the crystal to grow from the pencil-type tip located at a lower end of the crucible, a crystallized ingot is obtained. In addition, it is practiced to insert a seed crystal in the tip portion to control the orientation of the crystal plane of the ingot to some degree, but if the diameter of the ingot exceeds φ100 mm, control of the orientation becomes extremely difficult.

It is considered that the fluoride crystal fabricated by the Bridgman method basically has no predominance in the orientation of growth, and the horizontal plane of the ingot becomes a random plane for each crystal growth.

After crystal growth, since a large residual stress is present in the removed ingot, simple heat treatment is effected in the shape of the ingot as it is.

The ingot of the calcium fluoride single crystal thus obtained is cut and processed to an appropriate size by target product type. Here, in a case where the orientation of the crystal plane is not taken into consideration, to efficiently cut out a larger basic material for manufacturing an optical element (lens or the like) from the ingot, the ingot is cut (sectionally cut) horizontally. Subsequently, the basic material cut out is subjected to heat treatment for obtaining desired optical performance (homogeneity of the refractive index and birefringence).

As one example of the method for manufacturing a calcium fluoride single crystal using the above-described Bridgman method and heat treatment, Japanese Patent Application Laid-open No. 8-5801, for example, filed by the assignee of the present application discloses a method for obtaining an optical material whose refractive index difference is 5×10⁻⁶ or less by providing heat treatment after growing a fluorite single crystal by the Bridgman method.

Incidentally, since the fluoride single crystal exhibits high optical performance in a direction normal to a {111} crystal plane as compared to other crystal planes, it is practiced to measure the {111} crystal planes of an ingot of the fluoride single crystal, and to cut out a basic material for manufacturing an optical element such that the {111} planes become two parallel planes, followed by heat treatment.

Alternatively, a method is practiced in which after the ingot of the fluoride single crystal obtained by crystal growing is subjected to heat treatment for obtaining desired optical performance (homogeneity of the refractive index and the birefringence), and a basic material for fabricating an optical element is cut out so that the {111} crystal planes become two parallel planes, so as to obtain a fluoride single crystal of high optical performance.

Meanwhile, since the intrinsic birefringence of the fluoride crystal becomes greater as the measurement wavelength becomes shorter, in a projection lens of 193 nm or less, studies are being made to use a fluoride crystal in which the {100} planes or the {110} planes are two parallel planes, in addition to the fluoride crystal of the {111} plane. Even in the case of the fluoride crystal in which the {100} planes or the {110} planes are two parallel planes, a cutting-out step and a heat treatment step similar to those of the {111} plane are carried out.

In addition, to manage the intrinsic birefringence of the fluoride crystal and alleviate its effect, measurement of the crystal plane orientation in at least two directions by, for instance, the Laue method has been practiced.

In this document, the birefringence is a phenomenon in which the refractive index differs depending on the polarizing direction of the light (i.e., electromagnetic waves), and the polarizing direction in which the refractive index becomes minimum is referred to as the “fast axis,” and the polarizing direction in which the refractive index becomes maximum is referred to as the “slow axis.” The birefringence is generally represented by the optical path difference (called retardation) between the polarized light on the fast axis and the polarized light on the slow axis at the time when the light passes a unit length of a substance, and nm/cm is used as the unit. In addition, the birefringence occurs not only due to the intrinsic birefringence inherent in the substance or the crystal structure, but also there are cases where the birefringence occurs due to strains attributable to thermal stress and the like. There are cases where such a birefringence is simply called a strain.

The intrinsic birefringence has a value inherent in the substance independently of the crystal fabrication method and heat treatment conditions. Accordingly, even if the amount of birefringence and the orientation of the fast axis are not measured, if only the crystal plane orientation is measured, the amount of birefringence can be managed, and it is possible to overcome its effect by combining a plurality of optical members.

Meanwhile, with respect to the occurrence of the birefringence attributable to the thermal stress, by providing heat treatment in the same way as multicomponent optical glass and silica glass, the value of birefringence after heat treatment of the fluoride crystal becomes 1 to 2 nm/cm or thereabouts (measurement wavelength: 633 nm ) in the measurement in the optical axis direction. Thus it has been thought that the stress attributable to the thermal stress is lowered to a level which does not hamper free optical design.

For example, Japanese Patent Application Laid-open NO. 11-240798 filed by the assignee of the present application discloses a method for manufacturing a calcium fluoride single crystal having a large diameter and a small birefringence which is usable for photolithography with a wavelength of 250 nm or less. This method is characterized by subjecting the calcium fluoride single crystal to heat treatment under a specific temperature schedule. It is reported that, in this method, birefringences in a lateral direction perpendicular to the optical axis of the calcium fluoride single crystal after heat treatment were substantially the same at the rotational angle of 360° ([0047] of Japanese Patent Application Laid-open NO. 11-24079). For this reason, in its embodiment, the birefringence in a lateral direction (at an arbitrary direction) was measured without determining the crystal orientation in the lateral direction.

As a result of measuring the amounts of birefringence in various plane orientations of the calcium fluoride single crystal, the present inventors found that birefringences which cannot be suppressed by heat treatment remain in the calcium fluoride single crystal. Further, it was found that such a birefringence is at a level imparting adverse effects on the optical design. Furthermore, it was found that when a plurality of optical members are combined, this type of birefringence is not able to offset the effects. In other words, it is necessary to fabricate an optical system with optical members in which this type of birefringence is suppressed to a certain level or less.

### SUMMARY OF THE INVENTION

The present invention has been devised in view of the above-described problems, and it is an object of the present invention to provide an optical member formed of a fluoride single crystal in which the effect of birefringence is minimized, as well as a method for manufacturing the same. Another object of the present invention is to provide an exposure apparatus having the optical member of the present invention.

In accordance with the present invention, there is provided a method for manufacturing an optical member of a fluoride crystal, comprising:

a growing step of growing an ingot of a fluoride crystal;

a cutting-out step of cutting out from the ingot a cylindrical basic material with two parallel planes which have a certain crystal plane orientation;

an orientation-determining step of determining a crystal orientation of a side surface of the cylindrical basic material;

a birefringence-measuring step of measuring birefringence in a specific crystal axis direction at the side surface determined based on the crystal orientation determined in the orientation-determining step; and

an evaluating step of evaluating the fluoride crystal on the basis of a result of measurement of the birefringence.

When the present inventors measured the amounts of birefringence in various plane orientations of the calcium fluoride single crystal, it was found that there are cases where the birefringence attributable to thermal stress cannot be sufficiently suppressed according to a conventional method. Then, when a further study was made, it was found that the amount of birefringence at a side surface perpendicular to the optical axis of the calcium fluoride single crystal occurring due to the thermal stress varies substantially in dependence of the crystal orientation. Accordingly, the present inventors succeeded in sorting an optical member having excellent optical characteristics by determining in advance a specific crystal plane orientation in which the birefringence attributable to thermal stress becomes large, and by managing the amount of birefringence in that orientation. For example, in the case where two parallel planes are the {111} planes, it suffices if a determination is made as to whether or not the amount of birefringence in a specific crystal direction <110> at a side surface is a prescribed value or less. In the case where two parallel planes are the {100} plane, respectively, it suffices if a determination is made as to whether or not the amount of birefringence in a specific crystal direction <110> or <100> at the side surface is a prescribed value or less. Then, it suffices if only the member of the prescribed value or less is used as a material for forming an optical system such as a lens.

In particular, since optical lenses with large NA have recently been used to improve the resolution, in the light passing through the lens, components oblique to the optical axis increase in the light. These oblique components are affected by the distribution of the refractive index not only in the optical axis direction but in a direction perpendicular to the optical axis, i.e., in a lateral direction of the cylindrical crystal (in-plane direction perpendicular to the optical axis). Accordingly, by inspecting the amount of birefringence in the lateral direction perpendicular to the optical axis in accordance with the present invention, it becomes possible to determine whether or not the optical member is suitable for an optical system used for an exposure apparatus or the like.

In the above-described orientation-determining step, the crystal orientation at a side surface is determined by measuring the birefringence at the side surface at a plurality of angles. In the evaluating step, an evaluation can be made as to whether or not a maximum value of the birefringence in the specific crystal axis direction at the side surface is 10 nm/cm or less at a measurement wavelength of 633 nm. In a projection optical system used for an exposure apparatus, excellent image-forming characteristics are obtained by suppressing the maximum value of the birefringence in the specific crystal axis direction at the side surface to 10 nm/cm or less at the measurement wavelength of 633 nm. In the case where the maximum value of the birefringence in the specific crystal axis direction at the side surface is 10 nm/cm or less at the measurement wavelength of 633 nm, the aforementioned basic material can be formed into the shape of a predetermined optical member. If the case is otherwise, the cylindrical basic material can be appropriately disposed of as being unsuitable for the material of the optical member.

According to the present invention, an optical member of a fluoride crystal manufactured by the manufacturing method of the invention is provided. In this optical member, a maximum value of the birefringence in a specific crystal axis direction at a side surface of the fluoride crystal, which is shaped in a cylindrical shape with two parallel lined having a specific crystal plane orientation, is not more than 10 nm/cm at a measurement wavelength of 633 nm. The aforementioned fluoride crystal may be a calcium fluoride single crystal.

According to the present invention, an exposure apparatus having the optical member manufactured by the manufacturing method of the present invention is provided. This exposure apparatus has an excimer laser or an F₂ laser as a light source.

### BRIEF DESCRIPTION OF THE DRAWINGS

FIG. 1 is a conceptual view illustrating one example of a method for manufacturing an optical member in accordance with the invention;

FIG. 2 is a conceptual view illustrating a method of growing a calcium fluoride single crystal;

FIG. 3 is a view illustrating an apparatus for measuring a crystal plane orientation in accordance with the Laue method (side reflection method);

FIG. 4 is a conceptual view of α and β in a cylindrical member;

FIG. 5 is a conceptual view illustrating one example of a projection exposure apparatus;

FIG. 6 is a schematic view illustrating an example of a projection optical system;

FIG. 7 is a schematic view illustrating another example of the projection optical system;

FIG. 8 is a schematic view illustrating still another example of the projection optical system; and

FIG. 9 is a schematic view illustrating a further example of the projection optical system.

### DESCRIPTION OF THE PREFERRED EMBODIMENTS

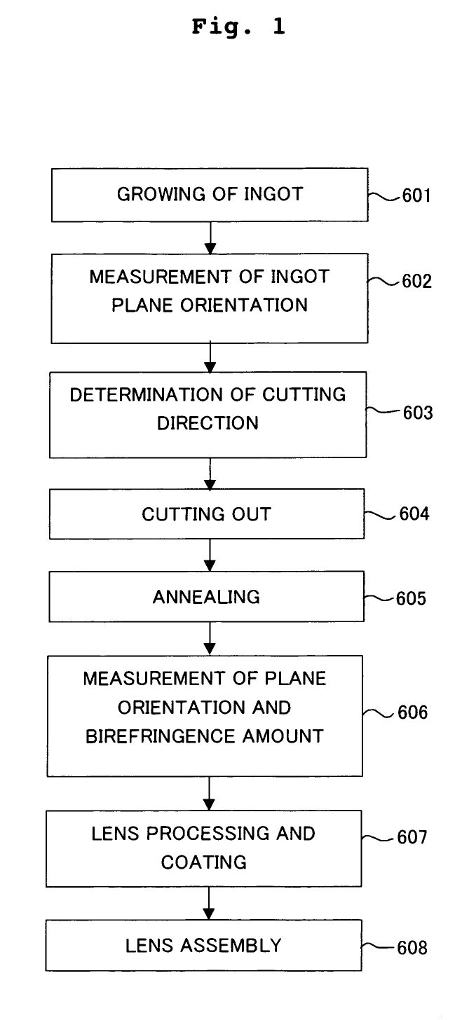

FIG. 1 shows an example of the flow chart of the method for manufacturing an optical member in accordance with the invention. The method for manufacturing an optical member in accordance with the invention basically includes the step of growing a crystal; the step of cutting out a cylindrical basic material and measuring the crystal orientation of a side surface of the basic material and birefringence; and a sorting step for determining the quality of the fluoride crystal or a method of use in accordance with the result of that measurement.

A crystal growing step 601 specifically includes a raw-material refining step, a preprocessing step, a crystal growth step, an annealing step in a crystal growing furnace, and the like.

A measurement step 602 for measuring the crystal plane orientation in ingot form is sometimes carried out prior to the step of cutting out the cylindrical basic material.

A cutting-out step 604 for cutting out the cylindrical basic material specifically includes an inspection step for inspecting foreign objects and the like in the inside, a cutting step, a rounding step, a plane polishing step, a chamfering step, and the like. In addition, at the time of cutting, a step 603 for determining a cutting plane and a cutting position by utilizing the Laue method, which will be described later, and a cleavage plane is taken.

After the cutting-out step, a step for measuring the crystal orientation of a side surface of the basic material and birefringence is taken, as required.

Further, an annealing step (heat treatment step) 605 is effected with respect to the cut-out basic material. The annealing step specifically has a temperature raising step for gradually raising the temperature within an annealing furnace, a holding step for holding the basic material at a fixed temperature, a temperature lowering step for gradually lowering the temperature, and a cooling-down step for allowing the basic material to cool by turning off a heater of the annealing furnace.

After the annealing step, a step 606 for measuring the birefringence of the basic material after annealing is executed. Specifically, measurement is made of the amount of in-plane birefringence of two parallel planes of the basic material, the distribution of the orientation of the fast axis, the amount of birefringence in the lateral direction, the orientation of the fast axis, and the like. The sorting of the basic material is effected on the basis of the results of this measurement. If the desired amount of birefringence has been obtained, the basic material is processed as it is into the lens shape (step 607), and undergoes an assembling step 608 to form an optical system. If the desired amount of birefringence has not been obtained, the basic material is subjected again to, for instance, the annealing step, and is thereby processed to assume a desired amount of birefringence.

The manufacturing method in accordance with the invention is characterized in measuring the crystal orientation in the lateral direction of the cylindrical basic material having two parallel planes cut out according to a predetermined crystal plane orientation, as well as the amount of birefringence in that orientation, the orientation of the fast axis, and the like.

The crystal plane orientation of the basic material does not change by heat treatment, but as for birefringence, the amount of birefringence and the orientation of the fast axis change before and after the heat treatment. Accordingly, in the present invention, it is made essential that the crystal plane orientation is measured at at least any one of the stages of the ingot state, before heat treatment, and after heat treatment, and that birefringence (amount and the fast axis) is measured at least after heat treatment.

For optimization of the birefringence, it is preferable to measure the crystal plane orientation and birefringences at the respective orientations before heat treatment, and appropriately determine the heat treatment conditions on the basis of this information.

It should be noted that when the crystal plane orientation in the lateral direction is measured before heat treatment, that orientation can be marked on the basic material, and that the birefringence in the orientation of that marking can be measured after heat treatment.

Further, it was confirmed by the present inventors that the amount of birefringence in the lateral direction has periodicity in the circumferential direction with respect to the crystal plane orientation, as will be described later. Accordingly, it is also possible to estimate the crystal plane orientation by measuring the amount of birefringence in the lateral direction from a plurality of angles without measuring the crystal plane orientation in the lateral direction. Namely, the crystal orientation of the side surface can be determined by measuring the amount of birefringence at a plurality of angles in the lateral direction.

Hereafter, a detailed description will be given of the respective steps.

<Crystal Growing Step>

As for the crystal growing step, a method similar to a conventional method for manufacturing a fluoride crystal is used. Hereafter, a description will be given of the method of growing a calcium fluoride single crystal according to the Bridgman method (Stockbarger or lowering method).

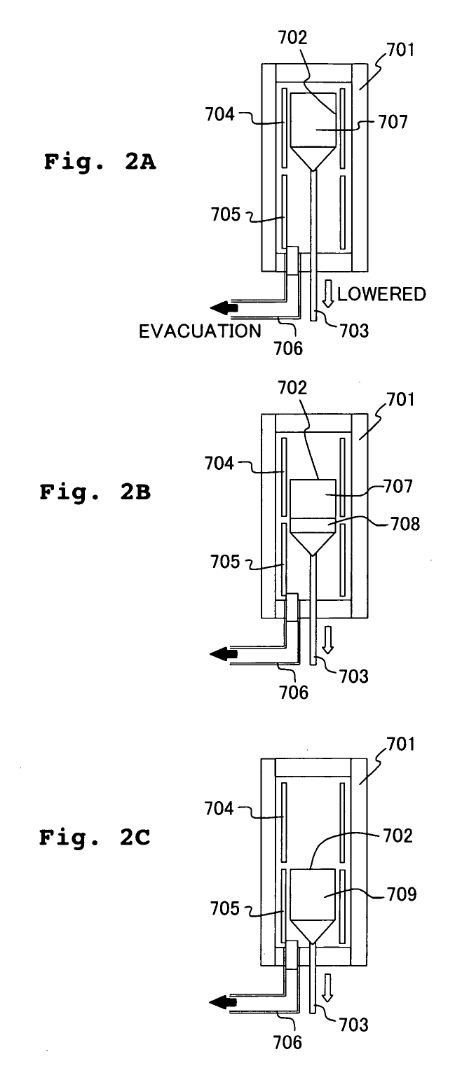

FIG. 2 is a conceptual view illustrating the method of growing a calcium fluoride single crystal.

A high-purity material fabricated by chemical synthesis is used as a raw material. First, a semi-molten article of the material is fabricated by the following procedure. A graphite crucible with the powdered material filled therein is placed in a superposed manner inside a preprocessing apparatus, and the interior of the preprocessing apparatus is kept in a vacuum atmosphere of 10⁻³ to 10⁻⁴ Pa. Next, the temperature within the preprocessing apparatus is raised to a level above the melting point of calcium fluoride (1370° C. to 1450° C.) to melt the raw material, and the temperature is subsequently lowered to room temperature. In this case, PID control is preferably effected so as to suppress the temporal change of the temperature within the apparatus. A fluorinating agent such as lead fluoride is added to this powdered material. A semi-molten article thus obtained is moved to a crystal growing furnace, and after the temperature is raised again to the melting temperature, the crucible is lowered at a rate of 0.1 to 5 mm/h or thereabouts in the crystal growing stage, thereby allowing crystallization to gradually take place starting from a lower portion of the crucible. When crystallization has occurred up to an uppermost portion of the melt, crystal growth is completed, and annealing (slow cooling) is effected by avoiding quenching (rapid cooling) so that the grown crystal (ingot) will not fracture. When the temperature within the growing apparatus has lowered to room temperature or thereabouts, the apparatus is opened to atmosphere, and the ingot is removed.

In this crystal growth, by using a φ300 mm-diameter crucible 702 made of graphite (carbon), a pencil-type ingot whose tip portion is conical is fabricated in a growing furnace 701 having heat insulating properties and airtightness. In this case, a single crystal can be formed by growing a crystal starting with a tip of the conical portion located at a lower end of the crucible. The crucible 702 is vertically movable by means of a support 703. In addition, a high-temperature side heater 704 and a low-temperature side heater 705 are disposed along the inner surface of the growing furnace 701 in an upper portion and a lower portion, respectively, of the growing furnace 701, so that the growing furnace 701 can be heated so that the lower portion of the furnace interior becomes lower than the upper portion thereof. Further, an exhaust line 706 for reducing the pressure within the furnace is installed in the lower portion of the growing furnace 701. First, a seed crystal is placed in a tip portion of the crucible. This seed crystal is aimed at controlling the orientation of crystal growth, but since the horizontal plane of the ingot actually becomes a random plane for each crystal growth, the orientation of the plane cannot be estimated at this stage.

In the growing step, as shown in FIG. 2A, the crucible with the material of the fluoride single crystal filled therein is first placed in an upper portion of the growing furnace 701, and air is vented through the exhaust line to keep the interior of the growing furnace in a vacuum atmosphere of 10⁻³ to 10⁻⁴ Pa. Next, the temperature within the growing furnace is raised to a level above the melting point of the fluoride (in the case of calcium fluoride: 1370° C. to 1450° C.) to melt the raw material.

Then, as shown in FIG. 2B, the crucible 702 is lowered at a predetermined rate (0.1 to 5 mm/h) by means of the support 703, and a melt 707 is allowed to gradually crystallize starting with the lower side of the crucible, thereby growing a fluoride single crystal 708.

Next, as shown in FIG. 2C, when the melt 707 has crystallized in the crucible up to an uppermost portion thereof, crystal growth is completed. The temperature is allowed to drop gradually inside the furnace down to room temperature or thereabouts so as to prevent a grown crystal 709 (ingot) from fracturing and to reduce the residual stress, and the ingot is subsequently taken out (A).

<Plane Orientation Measuring Step>

When a cylindrical (columnar) basic material is cut out from the ingot, the crystal orientation of at least two parallel planes is determined. Further, in this stage, two or more crystal orientations may be measured by using the Laue method or the like. Furthermore, the invention is not limited to measuring the crystal orientation of the entire ingot, and a test piece may be cut out from a top portion or a cone portion of the ingot and its crystal orientation may be measured, thereby determining the crystal orientation of the entire ingot. In addition, the crystal orientation may be measured in the state of a matrix in which the ingot has been cut or processed to some extent.

In the measurement of the plane orientation, the Laue method, for example, is used in which the crystal plane orientation is measured by irradiating a sample with X-rays.

The Laue method has an advantage in that various crystal plane orientations of such as {111}, {110}, and the like can be simply measured and controlled.

Since the Laue method is based on a lateral reflection method, the Laue method has an advantage in that measurement of even a large-diameter sample is possible without imparting damage to the sample.

At the time of determining the crystal orientation, it is desirable to suppress an angle of deviation from a desired orientation to within 3°. A detailed description will be given of a method of measuring the crystal orientation which is suitable for the invention.

Methods of evaluating the crystal orientation include methods based on X-rays, mechanical methods, optical methods, and the like.

Methods of evaluating the crystal orientation by X-ray include the Laue method in which the crystal set stationary is irradiated with X-rays, a rotating method or a vibrating method in which the crystal, while being rotated or vibrated, is irradiated with X-rays, the Walsenburg method or the precession method in which these methods are modified, and so forth.

Next, a description will be given of the mechanical methods.

If a plastic deformation is imparted to a crystal by an appropriate means, various surface patterns which are characterized by the crystal orientation appear on its surface. For example, such surface patterns include pressure figures (or percussion figures) having inherent shapes in the crystal planes, as well as slip bands, twins, and cleavages occurring along specific crystal planes. Of these, twin crystals include, in addition to plastic deformation by twinning, annealed twins and grown twins, and they similarly produce surface patterns.

Specifically, the mechanical methods include a method making use of a pressure figure, a method making use of a slip ellipse, a method making use of an angle of intersection between slip lines, twins, and other surface patterns, a method making use of a cleavage plane, analysis of slips, twins, and cleavages, and so forth.

In addition, the optical methods include the goniometric method, the etching-figure method, the light figure method, the ellipsometric method, and the like.

Of these measuring methods, the method using X-rays yields high measurement accuracy and a high speed, this method is suitable for use in the present invention. Hereafter, a description will be given of the method using X-rays.

In a case where an X-ray diffractometer is used, a Laue camera for back surface reflection is installed on a side opposite to a diffractometer of an X-ray tube. The distance between the sample surface and the film is set to several dozen millimeters. The X-ray tube uses a Mo target, and filming is effected at a tube voltage of 40 kV and a tube current of 50 mA for an exposure time of 60 sec. The analysis of the orientation is effected by hand calculation from a polaroid photograph of the Laue pattern obtained, or calculated by fetching the photograph into a computer by a scanner.

The Laue method is one of X-ray diffraction methods, and is so arranged that white X-rays strike a fixed single crystal. Since the Bragg angle θ is fixed with respect to all the planes of the crystal, each plane undergoes diffraction by selecting X-rays of a wavelength λ which satisfies the Bragg condition λ=2dsinθ with respect to the Bragg angle θ. As for the Laue method, there are three methods including the transmission method, the back-reflection method, and the side-reflection method by varying the relative positional relationship of the X-ray source, the crystal, the film or CCD camera. In the transmission method, the film or CCD camera is placed in the rear of the crystal to record beams which are diffracted in the forward direction. In the back-reflection method, the film is placed midway between the crystal and the X-ray source, and incident beams are passed through an aperture formed in the film, and the beams that are diffracted in the backward direction are recorded. In the side-reflection method, the X-ray source is disposed such that beams are made incident upon the crystal at a certain incident angle \overline{ω}, and the film or CCD camera is placed at a position rotated by φ with respect to the incident beam to record detracted beams in arbitrary side directions. In each of the methods, diffracted beams form Laue spots on the film or a fluorescent screen. Since the position of the Laue spot is determined by the relative relation of the crystal orientation with respect to the incident beam in each method, the position of the Laue spots is used in the determination of the crystal orientation by applying this fact.

The Laue method makes it possible to easily measure various crystal plane orientations of such as {111} and {110}, and is suitable for the present invention in terms of both measurement accuracy and the speed.

It should be noted that as a method of indicating the crystal orientation, Miller index is used. The Miller index is the reciprocal of a ratio of the distance from the origon of a unit lattice of a crystal to the point of intersection between the plane and the crystal axis to the unit length of the axis. In the case of a cubic system such as calcium fluoride, if it is assumed that the unit length of each crystal axis is a, the Miller index is (hkl) in a case where a certain plane intersects the axis at points of a/h, a/k, and a/l. In the cubic system, the orientation [hkl] is always perpendicular to the plane (hkl) of the same index, and directions which are in a symmetrical relation are represented by one index, and are shown by being bracketed by < >. Meanwhile, equivalent lattice planes which are in a symmetrical relation are also represented by one index, and are shown by being bracketed by { }. For example, oblique lines of a cube, such as [111], [1-11], [-1-11], and [-111] are all represented by <111>, and surfaces of a cube, (100), (010), (-100), (0-10), (001), (00-1) are represented by {100}.

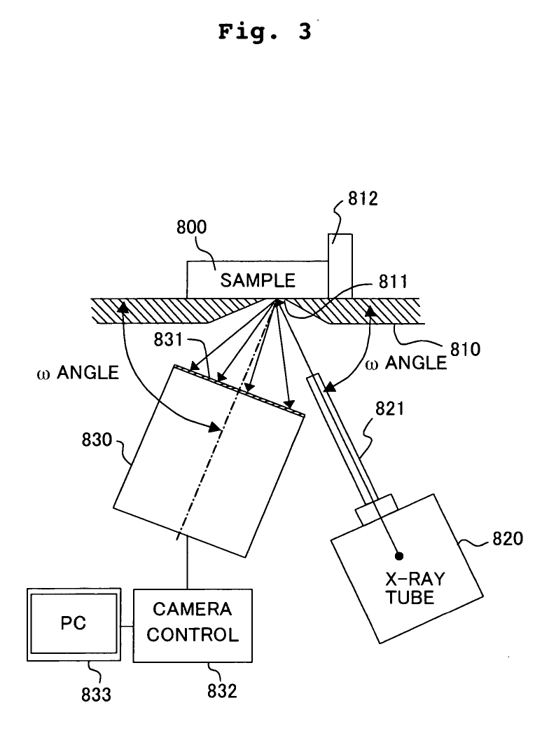

An apparatus for measuring the crystal orientation by the Laue method consists of an X-ray source, a sample stage, and a CCD camera (FIG. 3). X-rays are made incident upon the sample, and diffracted beams thereby obtained are analyzed as a Laue pattern.

In the present invention, it is proposed that the following method be preferably used for the measurement of a large sample such as a φ300×t60 block.

First, a measurement sample 800 is flatly placed on a stage 810, and an X-ray source (X-ray tube) 820 and an optical system of a film or CCD camera 830 are installed therebelow. Since the measurement sample 800 is flatly placed on the stage 810, it becomes possible to cope with a large sample. In addition, detailed measurement of mapping and the like is also made possible, and it suffices if spots are selected and a determination is made as to whether or not the simulation is correct, thereby enabling efficient measurement. Furthermore, as a result of the side-reflection method, damage to the sample by X-rays is made vary small.

Measurement of the crystal plane orientation by such a Laue method is executed. It should be noted that the measurement of the crystal plane orientation is synonymous with the measurement of the crystal axis. Namely, the measurement of the {111} plane orientation is equivalent to the measurement of the <111> axis.

By using the above-described measurement method, the plane orientation is managed in the procedure of cutting the top and the cone of the ingot, orientation measurement, estimation of the orientation of the ingot from data on the top and the cone, cutting out of the member, and measurement of the outside of the effective diameter of the member (mapping depending on the case) in the order mentioned.

Hereafter, the procedure of determining the plane orientation of the fluoride single crystal obtained by the Bridgman method will be specifically shown.

As for the ingot of the fluoride single crystal, a side portion which was facing the front in the furnace is scraped with a wire brush and is made smooth, and one straight line is drawn with a glass pencil and is set as a reference line of the position (B).

Subsequently, the conical shape (which will be referred to as a cone portion) at the tip and its opposite portion (which will be referred to as a top portion) are cut to a thickness of 30 mm, and are used as test pieces for plane orientation measurement (C). By effecting the plane orientation measurement of these two test pieces, the plane orientation of the main body portion is estimated. The positional relationship between the respective two test pieces and the ingot body is confirmed by the initial reference line of the position. The plane orientation measurement of the test pieces was carried out by the Laue method.

In addition, the entire ingot can be subjected as it is to the plane orientation measurement by the Laue method. However, the measurement of test pieces yields a greater advantage. This is because handling is difficult since the ingot weight reaches as much as several dozen kilograms, because calcium fluoride has a large coefficient of expansion, and its mechanical strength is not large, so that there is the risk of causing damage to the ingot, and because test pieces (φ30−60×t20) for management of transmittance and excimer laser resistance need to be cut out from the top and cone portions, and the cutting-out step is essential.

It should be noted since the single crystal of calcium fluoride (or barium fluoride) has a cleaving characteristic at the {111} plane, if the ingot is subjected to a thermal stress or the like, this single crystal breaks (cleaves) at the {111} plane. In addition, even in the case of the ingot which has not cleaved, if its end portion is lightly struck by a chisel or the like, it cleaves. If, by using this cleaved plane (cleavage plane) as a reference, the ingot is cut so as to be parallel to that plane, it is possible to cut a basic material for manufacturing an optical element. As for the basic material thus obtained, the {111} crystal planes are two parallel planes. Although there is a method in which the cleavage plane is thus used as a reference, according to the Laue method, each plane orientation can be measured instantaneously on a non-destructive basis.

A description will be given of an automatic measurement apparatus based on the Laue method. The automatic measuring apparatus is comprised of the X-ray source, the sample stage, and the CCD camera.

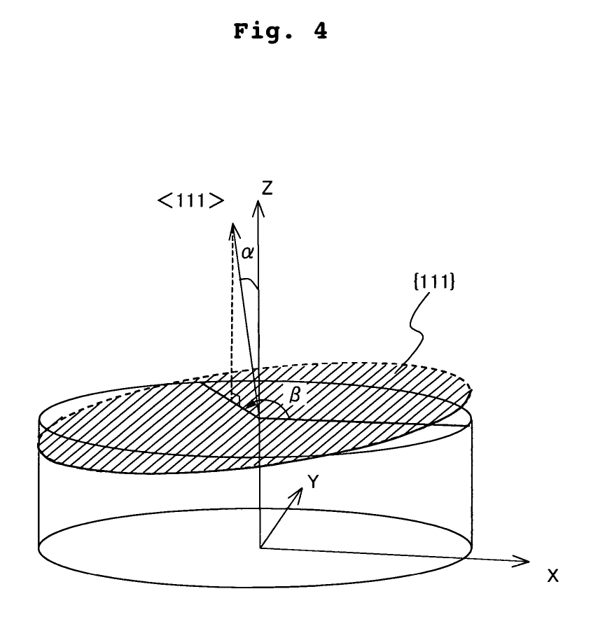

The structure provided is such that a sample is flatly placed on the stage, and the X-ray source and an optical system of the film or CCD camera are installed therebelow to make it possible to cope with a large sample. The test pieces of the top and cone portions are set such that the reference line is located at the front. Since the cone portion is conical, the cone portion is set with its flat portion facing downward for measurement. For this reason, measured values of the plane orientation are reversed to collate with the other portions. As the X-ray tube, one using a W target and having a maximum output of 2 kW, e.g., a tube voltage of 50 kV and a tube current of 40 mA, is used The X-rays generated in the X-ray tube are made incident upon the sample after being made substantially parallel by a double pinhole collimator of 1 mmφ or thereabouts and focused to a beam diameter of 2 mm or thereabouts. The X-ray irradiation time is about 1 minute. The diffracted beam is projected onto a fluorescent screen, is imaged by the CCD camera, and is fetched into the computer as a Laue pattern. The CCD is cooled to −50° C. by a Peltier element to improve its SN ratio. The fetched Laue pattern is analyzed on an orientation analyzing screen. The Laue pattern consists of a plurality of point rows, and one point row represents diffracted spots from the same zone axis of these, if four points are designated by a mouse from the spots (intersections of point rows) belonging to a plurality of zone axes, indexing is effected automatically, and a simulation pattern is displayed by being overlapped with a Laue pattern when matching is obtained. The degree of agreement of the two patterns is determined by a measurer. If the index is determined, a stereographic projection diagram, a stereographic triangle, and plane orientation angles of the respective planes are outputted as the results of orientation analysis. In a coordinate system in which the back of the sample stage is x-axis direction, and the vertical downward direction of the sample stage is z-axis direction, the plane orientation angles are expressed by setting as α an angle formed by the z axis and <111>, and by setting as β a angle formed by a line obtained by projecting <111> onto the measurement plane, in a counterclockwise direction from a+x direction of the x axis. FIG. 4 is a conceptual view of α and β in the cylindrical member.

Meanwhile, the remaining ingot body with the cone and top portions cut off is subjected to rounding, and the cylindrical surface portion is set as a surface equivalent to a sanding finished surface (E). It is also possible to observe an inner portion by surface grinding the side surface with a width of several centimeters (D). In addition to the observation from the surface at the sanded surface, the inner portion is observed in a darkroom by applying matching oil for the refractive index, stress concentrations and the like at the interface are observed by a cross Nicol optical system, and states of the sub-grain boundary and polycrystals, and the position of the interface are confirmed. Furthermore, the conditions of bubbles and foreign objects are also concurrently confirmed. If the entire ingot has grown into a single crystal, if the plane orientation at one of the cone and top portions is measured, the plane orientation of the entire ingot can be estimated. In order to be more accurate, it is preferable to measure the respective plane orientations at the cone and the top, and confirm that there is no discrepancy between their plane orientations. Further, there are many cases where the ingot has become polycrystals, and sub-grain boundaries are present. In such a case, it is necessary to measure the crystal orientation for each portion of the single crystal in the ingot.

<Step of Determining Cutting Orientation and Cutting>

The direction of cutting the ingot is determined on the basis of α and β determined by the above-described test pieces. When the orientation angle of the top portion is used, a side surface in a (90°−β) direction in a case where when the ingot is viewed from the direction of the top, the counterclockwise rotation from the direction of the reference line about a plane normal line of a cut plane of the top portion is set as positive is used as a bearing surface. Meanwhile, a clockwise a direction using the cut section of the top portion as a reference plane is set as a cutting direction. When the orientation angle of the cone portion is used, a side surface in a (90°−β) direction in a case where when the ingot is viewed from the direction of the cone, the counterclockwise rotation from the direction of the reference line about a plane normal line of a cut plane of the cone portion is set as positive is used as a bearing surface (reference plane of processing). Meanwhile, a clockwise a direction using the cut section of the top portion as a reference plane is set as a cutting direction (F). Further, a cutting position is determined by incorporating a processing allowance in the annealing step, i.e., dimensions of +5 to 10 mm for both thickness and diameter, into a desired part size (G). In cutting, a ground surface (bearing surface) parallel to the axis of the ingot is first formed in the bearing surface direction of the ingot side surface set from the plane orientation angle, the ingot is placed on the stage of a cutting machine with the bearing surface facing downward. The ingot is cut by being rotated by α by using the top surface as the reference plane (H). As for the elliptical disk obtained by cutting, its inner portion is observed in a darkroom by applying matching oil for the refractive index thereto, stress concentrations and the like at the interface are observed by a cross Nicol optical system, and states of the sub-grain boundary and polycrystals, and the position of the interface are confirmed. Furthermore, cutting (rough cutting) (I) and rounding (J) are effected after determining the position of the part cutting by incorporating a processing allowance in the annealing step, i.e., dimensions of +5 to 10 mm for both thickness and diameter, into a desired part size while avoiding the positions of bubbles and foreign objects in the ingot. Further, rough grinding and chamfering are effected for inspecting the plane orientation (K). In this case, the plane orientation of a final member can also be managed as such a marking that clarifies the relationship with the plane orientation determined from the initially marked reference line is maintained also in the subsequent steps.

As the plane-orientation determining step is provided before the cutting-out step, angle of deviation of the manufactured optical member from a desired orientation can be set to within 3°. This angle can be used up to 4°, a maximum of 6° or thereabouts in a most deviating state, but 3° or less is desirable, and 2° or less is particularly desirable.

The Laue method used in the present invention is not limited to the management of such plane orientations, but can be also used in the detection and management of sub-boundaries and twins. Slight sub-boundaries are not easily detected by visual observation, and a skilled person normally needs to detect them by obliquely applying the light to the ground surface. If such mapping measurement is effected, in a case where sub-boundaries are present, deviations of the plane orientation of several degrees or thereabouts are present, they can be easily detected.

<Heat Treatment Step>

As for the two cylindrical basic materials of φ260×t50 and φ200×t60 thus obtained, after their crystal plane (axis) orientations in the lateral direction are measured, and the amount of birefringence in that direction and the orientation of the fast axis are measured, heat treatment (annealing) is provided for the improvement of the quality. The measurement of the birefringence of the light transmitted in a direction perpendicular to the normal direction of the two parallel planes, i.e., the lateral direction of the member, will be referred hereafter to as the measurement in the lateral direction.

<Step of Measuring Plane Orientation and Birefringence>

A method similar to the plane orientation measurement of the ingot based on the above-described Laue method is used in the measurement in the lateral direction.

The plane orientations of the two parallel planes are determined as being such as the {111} plane and the {100} plane, and the measurement in the direction of the optical axis is uniform. However, in the measurement in the lateral direction, arbitrariness of 180° is present toward the center of the member. In the case where the two parallel planes are the {111} planes, the optical axis direction becomes the <111> axis, but the <110> axis and the <211> axis, for example, are present in the lateral direction perpendicular thereto. In the case where the two parallel planes are the {100}, the optical axis direction becomes the <100> axis, but the <100> axis and the <110> axis, for example, are present in the lateral direction perpendicular thereto. As a result of making detailed measurement of the lateral direction by the present inventors, it was found that certain periodicity is present in the 180° rotational direction, and that the birefringence in the lateral direction assumes a maximum (maximal) value in the direction of the <110> axis in the case where the two parallel planes are the {111} planes, and in both the direction of the <110> axis and the direction of the <100> axis in the case where the two parallel planes are the {100} planes.

Accordingly, the relationship between the crystal plane orientation in the lateral direction and birefringence is measured by the measurement in the lateral direction.

In this measurement, the crystal plane orientation in a specific lateral direction is measured by, for instance, the Laue method, the amount of birefringence in that orientation is measured, and the amount of birefringence in the lateral direction having a predetermined angle from that orientation is consecutively measured. Specifically, in the case where the two parallel planes are the {111} planes, the amount of birefringence in the direction of the <110> axis of the side surface is measured. In this case, the <110> axis is present in the 120° rotational direction in the lateral direction. Preferably, by using a specific <110> axis direction as a reference, the amount of birefringence is measured at angular intervals in the rotational direction, e.g., in units of 30°, preferably in units of 10° or thereabouts.

It is true that even if the crystal plane orientation in the lateral direction is not measured by the Laue method, if the above-described periodicity is made use of, it is possible to estimate the crystal plane orientation in the lateral direction. Namely, the amount of birefringence is measured in the 180° rotational direction in, for example, units of 10° by using an arbitrary position in the lateral direction as a reference. The direction of a maximum value thus obtained becomes the <110> axis in the case where the two parallel planes are the {111} planes, and the <110> axis or the <100> axis in the case where the two parallel planes are the {100} planes.

As described above, the crystal plane orientation, the amount of birefringence, and the orientation of the fast axis in the lateral direction prior to heat treatment are measured.

At this time, it is preferable to provide marking to maintain the crystal orientation of the basic material during annealing. A soft pencil or red oil based ink, which does not cause damage to the surface of the calcium fluoride and does not produce impurity contamination, is used for the marking. Since red oil based ink turns black after annealing, the discrimination before and after annealing becomes possible.

Further, mapping measurement of the in-plane plane orientation of the two parallel planes of the basic material is carried out. In the plane orientation measurement involving X-ray irradiation as in the Laue method, damage is caused to the calcium fluoride basic material, and causes a color center. Therefore, the stage of the basic material having an extra thickness of 2.5 to 5 mm in terms of a final lens shape is suited to mapping measurement. After the shape of the basic material has become closer to the lens shape, only the outside of the effective diameter in the optical design, i.e., a peripheral range of several millimeters, can be undesirably measured.

In the present invention, it is preferable to precisely manage the angular deviation of the crystal plane. At the time of measuring the angular deviation, an apparatus is used which is based on the side-reflection Laue method for measuring an angular deviation between the sample surface and the crystal plane from the Laue spots obtained by side reflection. As for the Laue method, the back-reflection method or the transmission method is generally used, in which case it is preferable to manage the transmittance after X-ray irradiation so as to minimize damage to the sample.

<Heat Treatment Step>

Thereafter, the basic material whose crystal plane orientation and birefringence have been measured is subjected to heat treatment so as to improve the optical performance such as birefringence.

The cylindrical basic material is placed in a container of a heat treatment apparatus so that the flat surfaces become upper and lower sides, and heat treatment (annealing: a heat treatment temperature of 1080° C.) is provided by heating by a heater (L).

The heat treatment apparatus is a vacuum apparatus, and is structured to prevent the entry of oxygen which causes the haze of calcium fluoride. The external structure is made of stainless steel, and a graphite heater and a graphite container are installed in its interior. To completely eliminate the internal oxygen and to coat the metal exposed to the in-furnace surface with a fluoride, approximately 100 g of acid ammonium fluoride is sealed in the furnace together with calcium fluoride simultaneously with the calcium fluoride member. In that state, after the interior of the furnace is set in a vacuum state by a vacuum pump, temperature rising is started. Shortly before and after the in-furnace temperature exceeds 500° C., vaporization of acid ammonium fluoride starts, so that the in-furnace pressure turns to a weak positive pressure. The temperature is raised while controlling the pressure so that this weak positive pressure (2 to 8 kPa) will be maintained, the temperature is then held at 1080° C., and annealing is effected.

By effecting the above-described annealing, it is possible to reduce the amount of birefringence attributable to thermal stress in specific crystal plane orientations of the calcium fluoride member.

In particular, when the temperature is held at a predetermined level, heat treatment is effected such that the temperature distribution inside the bulk (member) during the temperature drop and radiational cooling falls within 0.5° C. at both times, thereby making it possible to reduce the amount of birefringence in predetermined crystal plane orientations of the side surfaces.

The heat treatment apparatus should preferably be provided with a heat insulating material or a heater disposed in such a manner as to cover the entire surface of the subject material (calcium fluoride basic material). To improve a thermal homogeneity condition in the apparatus, it is preferable to use an apparatus having a sufficiently large capacity, e.g., a capacity 10-fold or more the member, with respect to the member.

In addition, to further improve thermal homogeneity, it is preferable to rotate the subject material inside the heat treatment apparatus.

Alternatively, if a heat treatment apparatus is used in which a heater is disposed to as to bring about such a heat distribution as to offset the circumferential distribution of the amount of birefringence in accordance with the results of measurement of the crystal plane orientations of the side surfaces of the cylindrical basic material and the amounts of birefringence at the respective orientations, it is possible to reduce the amount of birefringence in the lateral direction of the basic material which is the subject material.

A window is worked in the side surface of the cylindrical basic material subjected to heat treatment, and its upper and lower surfaces are ground by 2.5 mm each (M). Then, the homogeneity of the birefringence and the refractive index of the side surface are confirmed (N). Subsequently, rounding is effected (O).

After annealing, polishing (tentative gloss forming) and chamfering are effected (P), and automatic measurement is made of values of birefringence of the light traveling in the normal direction of the two parallel planes with respect to about 200 points by using an automatic birefringence measuring apparatus made by ORC Manufacturing Co. Ltd. or Uniopto (measurement wavelength is 633 nm ). This measurement is referred to as the measurement in the optical axis direction. In addition, measurement is also made of the birefringence of the light transmitted in a direction perpendicular to the normal direction of the two parallel planes, i.e., in the lateral direction of the member. In a case where the outer periphery is circular, such an auxiliary tool as to allow the light to straightly travel is necessary, but automatic measurement becomes possible by contriving the holding of the member. This measurement is referred to as the measurement in the lateral direction.

By virtue of the above-described various heat treatment methods, in the present invention, it has become possible to make small an absolute value of the amount of birefringence in the side surface of the basic material irrespective of the crystal orientation.

As the amount of birefringence in the lateral direction is thus reduced, control of intrinsic birefringence attributable to the crystal plane orientation is facilitated. Namely, the birefringence attributable to the thermal stress in the invention is measured and managed at a wavelength of 633 nm. However, in order to accurately manage the effect of intrinsic birefringence which becomes large at a wavelength (e.g., 193 nm or the like) which is actually used in an optical member, it is extremely effective to minimize the amount of birefringence attributable to the thermal stress at 633 nm.

<Example of Projection Exposure Apparatus>

Next, an example is shown of a projection exposure apparatus on which an optical member formed of a fluoride crystal obtained in accordance with the invention is mounted.

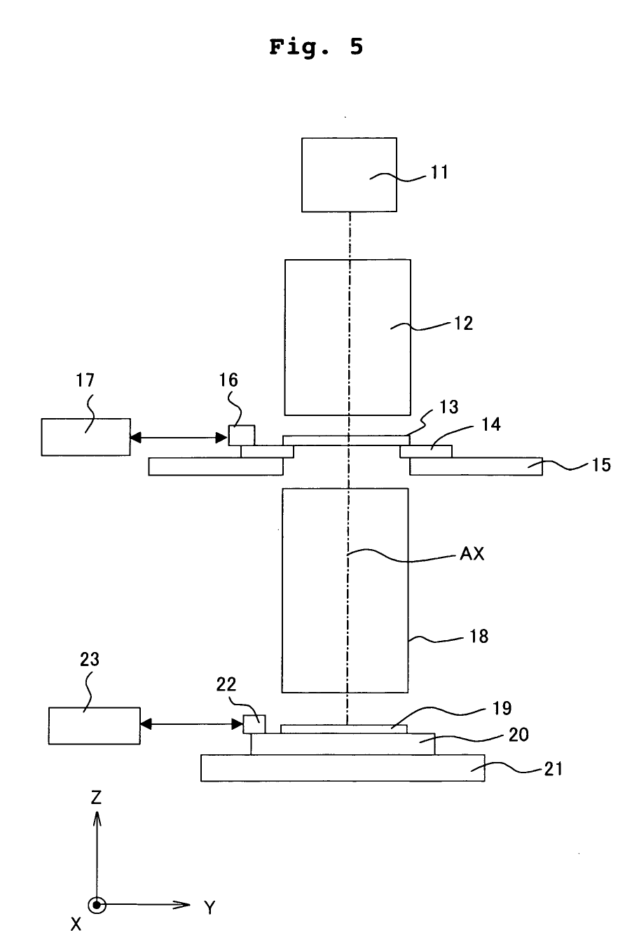

The projection exposure apparatus shown in FIG. 5 has an F₂ laser (wavelength: 157 nm ) as a light source 11 for supplying illuminating light of an ultraviolet zone. The light emitted from the light source 11 uniformly illuminates a mask 13 with a predetermined pattern formed thereon through an illuminating optical system 12.

It should be noted that one or a plurality of bending mirrors for changing the optical path are disposed, as required, in the optical path from the light source 11 to the illuminating optical system 12. In addition, the illuminating optical system 12 is formed by, for example, a fly-eye lens, an internal reflection-type integrator, or the like, and has an optical system including a field stop for defining a surface light source of a predetermined size and shape, as well as a field-stopped image-forming optical system or the like for projecting a field-stopped image onto the mask 13. Further, the optical path between the light source 11 and the illuminating optical system 12 is hermetically sealed by a casing (not shown), and the space from the light source 11 to the optical member disposed on a side close to the mask 13 in the illuminating optical system 12 is substituted by an inert gas (nitrogen, helium, or the like) having a low absorbance of the exposure light.

The mask 13 is held on a mask stage 15 in parallel to the XY plane by means of a mask holder 14. A pattern to be transferred has been formed on the mask 13, and, of the entire pattern region, a slit-like pattern region having a long side along the Y-axis direction and a short side along the X-axis direction is illuminated.

The mask stage 15 is two-dimensionally movable along the mask surface (XY plane), and its position coordinates are arranged to be measured and controlled by an interferometer 17 using a mask moving mirror 16.

The mask 13, the mask holder 14, and the mask stage 15 thus arranged between the illuminating optical system 12 and a projection optical system 18 are accommodated in a casing (not shown), and the interior of the casing is substituted by an inert gas (nitrogen, helium, or the like).

The light from the pattern formed on the mask 13 forms a mask pattern image on a wafer 19, i.e., a photosensitive substrate, through the catadioptric type projection optical system 18. The wafer 19 is held on a wafer stage 21 in parallel to the XY plane by means of a wafer holder 20. Further, a pattern image is formed on the wafer 19 in a slit-like exposed region having a long side along the Y-axis direction and a short side along the X-axis direction, so as to optically correspond to the slit-like illuminated region on the mask 13.

The wafer stage 21 is two-dimensionally movable along the wafer surface (XY plane), and its position coordinates are arranged to be measured and controlled by an interferometer 23 using a wafer moving mirror 22.

The wafer 19, the wafer holder 20, and the wafer stage 21 are accommodated in a casing (not shown), and the interior of the casing is substituted by an inert gas (nitrogen, helium, or the like).

Thus, in the projection exposure apparatus shown in FIG. 5, an atmosphere in which the absorption of the exposure light is suppressed is formed in the entire region of the optical path from the light source 11 to the wafer 19.

In addition, the shapes of the illuminated region (field region) of the mask 23 formed by the projection optical system 18 and the projected region (exposed region) on the wafer 19 are slit shapes having the short side along the X-axis direction. Accordingly, as the mask stage 15 and the wafer stage 21, or together with the mask 13 and the wafer 19, are synchronously moved along the short side direction (X-axis direction) of the slit-like illuminated region and the exposed region while performing position control of the mask 13 and the wafer 19 by using a drive system, the interferometers 17 and 23, and the like, scanning and exposure are effected on the wafer 19 with respect to the region having a width equal to the long side of the exposed region and a length corresponding to the amount of scanning (amount of movement) of the wafer 19.

Then, as optical members (lenses, prisms, and the like) constituting the illuminating optical system 12 and the projection optical system 18, it is effective to use optical members which have been subjected to management of two or more crystal plane orientations in accordance with the invention.

The projection exposure apparatus shown in FIG. 5 is one example, and optical members fabricated in accordance with the invention may be applied to various projection exposure apparatuses such as those disclosed in U.S. Pat. No. 6,341,007B1.

<Example of Projection Optical System>

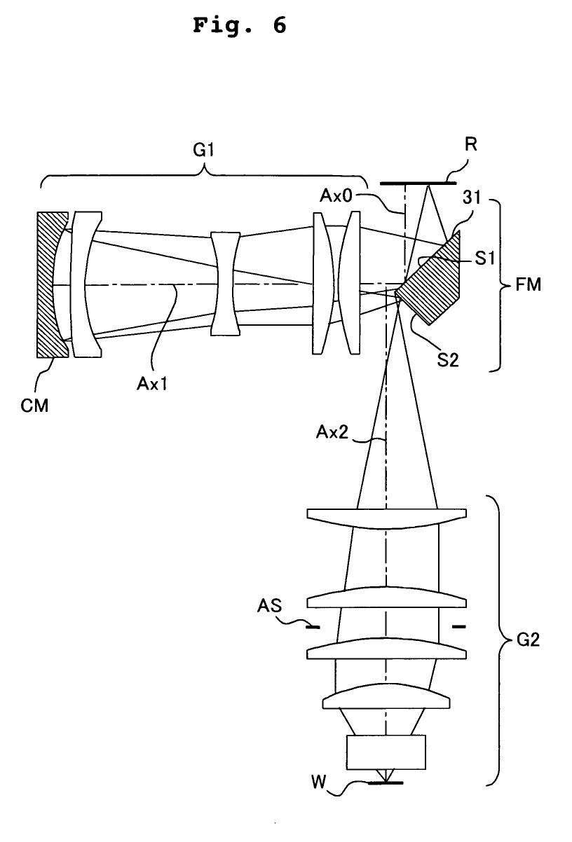

FIG. 6 is a schematic view illustrating one example of the projection optical system used in the projection exposure apparatus in accordance with the invention.

In FIG. 6, the projection optical system has a first image-forming optical system G1 of a catadioptric type for forming an intermediate image of the pattern on a reticle R serving as a projection original plate, as well as a second image-forming optical system G2 of a refraction type for allowing the intermediate image obtained by the first image-forming optical system G1 to be formed again on a wafer W serving as a workpiece. Disposed on an optical axis AX1 is an optical-path bending member having an optical-path-bending reflecting mirror 31 having a reflecting surface S1 for deflecting the optical path 90° from the reticle R toward the first image-forming optical system G1 and a reflecting surface S2 for deflecting the optical path 90° from the first image-forming optical system G1 toward the second image-forming optical system G2.

The first image-forming optical system G1 has a plurality of lens components and a concave reflecting mirror arranged along the optical path AX1, and forms an intermediate image with a substantially equal magnification or a slightly reduced magnification.

The second image-forming optical system G2 has a plurality of lens components a arranged on an optical path AX2 perpendicular to the optical axis AX1 as well as a variable aperture stop AS for controlling the coherence factor, and forms a secondary image with a predetermined reduced magnification on the basis of the light from the intermediate image.

Here, an optical axis AX0 in FIG. 6 is an optical axis which is located between the reticle R and a reflecting mirror 31 and which is perpendicular to the optical axis AX1 of the first image-forming optical system G1. The optical axis AX0 and the optical axis AX2 may align on an identical straight line.

In addition, FIG. 6 shows the projection optical system provided with the first image-forming optical system G1 and the second image-forming optical system G2 respectively having a plurality of lens components, but the lens components arranged along the optical axes AX1 and AX2 may be either singular or plural.

Furthermore, the angle formed by the optical axis AX0 and the optical axis AX1 may not necessarily be 90°, and may be an angle obtained by, for example, rotating a concave reflecting mirror CM counterclockwise. At this time, it is preferable to set the angle of bending the optical axis by a reflecting surface S2 such that the reticle R and the wafer W become parallel.

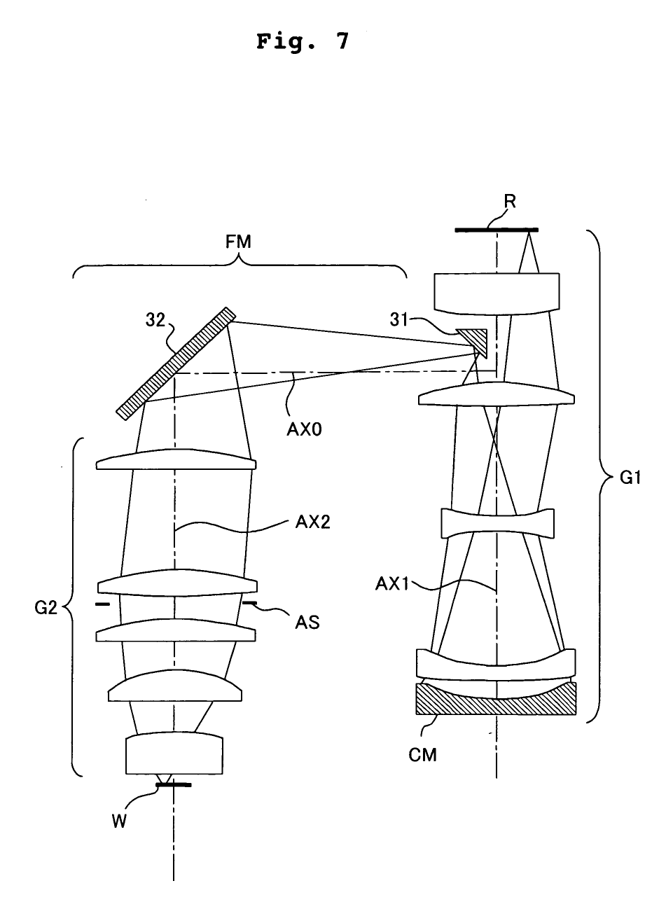

In addition, in the present invention, it is also possible to use a projection optical system having two reflecting mirrors 31 and 32, as shown in FIG. 7.

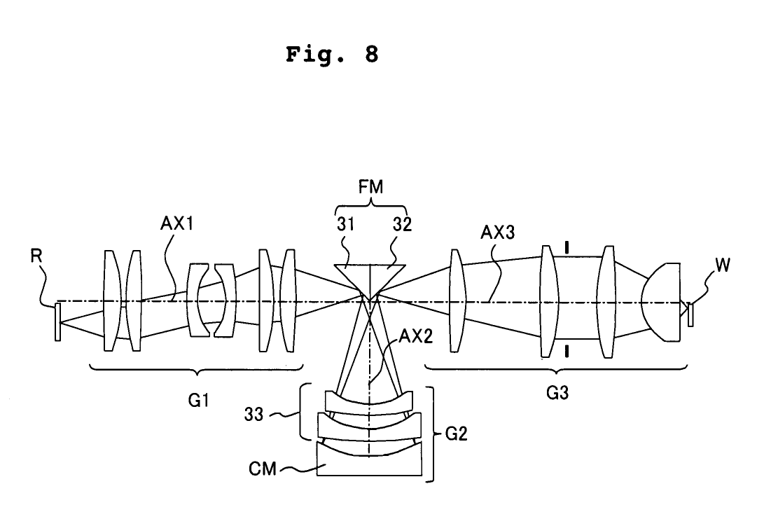

Further, in the present invention, it is also possible to use a projection optical system having the configuration shown in FIG. 8.

In FIG. 8, the projection optical system has the first image-forming optical system G1 of the catadioptric type for forming an intermediate image of the pattern on the reticle R serving as a projection original plate. A first optical-path-bending reflecting mirror 31 is disposed in the vicinity of a first intermediate image which is formed by the first illuminating optical system G1. The light beam directed toward the first intermediate image or the light beam from the first intermediate image is deflected toward the second illuminating optical system G2 by the first optical-path-bending reflecting mirror 31. The second illuminating optical system G2 has the concave reflecting mirror CM and at least one negative lens 33, and forms a second intermediate image (an image of the first intermediate image and a secondary image of the pattern) of a substantial equal magnification to that of the first intermediate image on the basis of the light beam from the first intermediate image.

A second optical-path-bending reflecting mirror 32 is disposed in the vicinity of the position for forming the second intermediate image which is formed by the second illuminating optical system G2. The light beam directed toward the second intermediate image or the light beam from the second intermediate image is deflected toward a third illuminating optical system G3 by the second optical-path-bending reflecting mirror 32. It should be noted that the reflecting surface of the first optical-path-bending reflecting mirror 31 and the reflecting surface of the second optical-path-bending reflecting mirror 32 are arranged so as not to spatially overlap with each other.

The third illuminating optical system G3 forms a reduced image (an image of the second intermediate image and a final image of the catadioptric optical system) of the pattern of the reticle R on the wafer W serving as a workpiece (a photosensitive substrate) disposed on a second surface on the basis of the light beam from the second illuminating optical system.

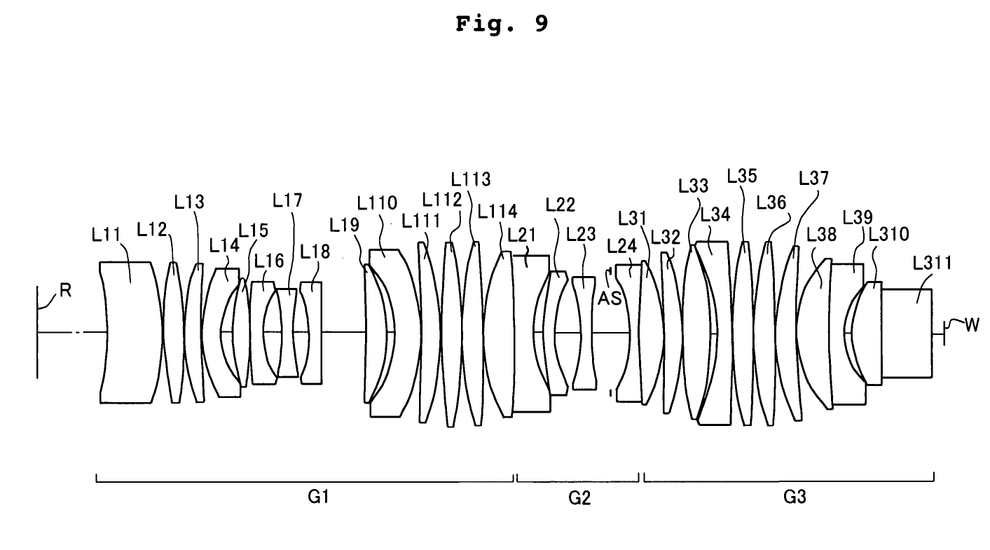

The projection optical systems shown in FIGS. 6 to 8 are suitably used in cases where, for instance, the exposure light source is an F₂ laser. Meanwhile, in a case where the exposure light source is an ArF excimer laser, a projection optical system having, for instance, a lens configuration shown in FIG. 9 is suitably used.

In FIG. 9, a first lens group G1 of positive power, a second lens group G2 of positive power, and a third lens group G3 of negative power are formed in that order from the side of the reticle R serving as a first object. This projection optical system is substantially telecentric on the object side (reticle R side) and the image side (wafer W side), and has a reduced magnification. Further, the numerical aperture (N.A.) of this projection optical system is 0.6, its magnification of projection is ¼, and the diameter of the exposed region on the image side is 30.6.

In a case where the projection optical system has a lens configuration shown in FIG. 9, the material of each lens is normally selected appropriately to correct chromatic aberrations. For example, correction of chromatic aberrations can be suitably effected by using silica glass as the material of 14 lenses L11 to L114 constituting the first lens group G1, silica glass as the material of 4 lenses L21 to L24 constituting the second lens group G2, a calcium fluoride crystal as the material of the lenses L31, L33, L35, L37, L38, and L310 among 11 lenses L31 to L311, and silica glass as the material of the remaining 5 lenses, respectively constituting the third lens group G3.

### EXAMPLE 1

An ingot was fabricated by using the Bridgman method. A high-purity material made by chemical synthesis was used as a raw material. Graphite crucibles with the powdered material filled therein were placed in a superposed manner inside in a growing apparatus, and the interior of the growing apparatus was kept in a vacuum atmosphere of 10⁻³ to 10⁻⁴ Pa. Next, the temperature within the growing apparatus was raised to a level above the melting point of calcium fluoride to melt the raw material, and the temperature was subsequently lowered to room temperature. In this case, PID control was carried out to suppress the temporal change of the temperature within the growing apparatus. Lead fluoride as a fluorinating agent was added to this powdered material. A semi-molten article thus obtained was moved to a crystal growing furnace, and after the temperature was raised again to the melting temperature, the crucible was lowered at a speed of 0.1 to 5 mm/h or thereabouts in the crystal growing stage, thereby allowing crystallization to gradually take place starting from a lower portion of the crucible. When crystallization occurred up to an uppermost portion of the melt, crystal growth was completed, and annealing was effected by avoiding quenching so that the grown crystal (ingot) would not fracture. When the temperature within the growing apparatus lowered to room temperature or thereabouts, the apparatus was opened to atmosphere, and an ingot of φ290×t300 mm was removed.

In this crystal growth, a pencil-type crucible whose tip portion was conical was manufactured by using a φ300-mm graphite crucible. A seed crystal was inserted in a tip portion of the conical portion located at a lower end of the crucible to allow a crystal to grow while the plane orientation in crystal growth was being controlled, thereby obtaining a single crystal. Since the ingot which is removed has a very large residual stress, the temperature of the ingot in the furnace was allowed to drop gradually down to room temperature.

The conical shape (referred to as the cone portion) at the tip of the ingot of the calcium fluoride single crystal thus obtained, as well as its opposite portion (referred to as the top portion), were respectively cut to a thickness of 30 mm (diameter: 290 mm ), and the pieces thus cut out were used as test pieces for measuring of plane orientation. The plane orientation of the main body portion was estimated by measuring the plane orientation of these two test pieces. The measurement of the plane orientation of the test pieces was effected in accordance with the Laue method.

The plane orientations of two cylindrical basic materials of φ260×t50 and φ200×t60, in which the plane orientations of the two parallel planes were {111} planes, were cut out, and birefringence was measured. As for objects to be measured, measurement was made of the in-plane distribution of birefringence of the {111} plane, as well as 18 directions in units of 10° by using the <110> direction as a reference in accordance with the crystal plane orientation of the side surface determined in advance by the Laue method.

As a result of measurement, the birefringence in the optical axis direction at the {111} crystal plane before heat treatment was 10 nm/cm or more. In addition, as for the lateral direction, the <110> direction exhibited a maximum value of 12 nm/cm. Accordingly, heat treatment of this basic material was carried out.

The cylindrical basic material was placed in a heat treatment apparatus so that the flat surfaces became upper and lower sides, and heat treatment (heated to and held at 1080° C., followed by annealing) was provided by heating by a heater. At that time, adjustment of the temperature schedule was made so that the temperature distribution inside the member fell within 0.5° C. during each time of holding, temperature drop, and radiational cooling.

The heat treatment apparatus was a vacuum apparatus, and was structured to prevent the entry of oxygen which causes the haze of calcium fluoride. The external structure was made of stainless steel, and a graphite heater and a graphite container were installed in its interior.

As for the graphite container, one having a sufficiently large capacity (a capacity 10-fold or more that of the basic material) with respect to the member was used. Approximately 100 g of acid ammonium fluoride was sealed in the graphite container together with the calcium fluoride member. After the interior of the furnace was set in a vacuum state by a vacuum pump, temperature rising was started. The temperature was raised while controlling the pressure so that the in-furnace temperature was kept at a weak positive pressure (2 to 8 kPa), the temperature was then held at 1080° C., and annealing was effected.

As a result of the above-described heat treatment, the birefringence in the optical axis direction at the {111} crystal plane after the heat treatment of the calcium fluoride member became 0.8 nm/cm. In addition, as for the lateral direction, the <110> direction exhibited a maximum value of 2.5 nm/cm. The maximum value of this birefringence satisfies the requirement as a lens optical member of a projection optical system used for an exposure system. For this reason, a lens optical member was formed by using this basic material.

### EXAMPLE 2

A calcium fluoride single-crystal ingot was grown by a method similar to that of Example 1. A plurality of cylindrical members were cut out from this ingot such that the {100} planes became the two upper and lower planes. The birefringence in the optical axis direction at the {100} crystal planes of the cut-out members was 20 nm/cm or more (before heat treatment). In addition, the birefringence in the lateral direction of this member exhibited a maximum value of 18 nm/cm in the <110> direction. Accordingly, heat treatment was carried out in the same way as in Example 1. As a result of this heat treatment, the birefringence in the optical axis direction at the {100} crystal planes of the calcium fluoride member became 2.8 nm/cm. In addition, the birefringence in the lateral direction exhibited a maximum value of 5.9 nm/cm in the <110> direction. The maximum value of this birefringence satisfies the requirement as a lens optical member of a projection optical system used for an exposure system. For this reason, a lens optical member was formed by using this basic material.

### EXAMPLE 3

A calcium fluoride single-crystal ingot was grown by a method similar to that of Example 1. A plurality of cylindrical members were cut out from this ingot such that the {100} planes became the two upper and lower planes. The birefringence in the optical axis direction at the {100} crystal planes of the cut-out members was 20 nm/cm or more (before heat treatment). In addition, the birefringence in the lateral direction exhibited a maximum value of 18 nm/cm in the <110> direction. Accordingly, heat treatment of this member was carried out.

The cylindrical basic material was placed in the heat treatment apparatus so that the flat surfaces became upper and lower sides, and heat treatment (heated to and held at 1080° C., followed by annealing) was provided by heating by a heater. The heat treatment apparatus was a vacuum apparatus, and was structured to prevent the entry of oxygen which causes the haze of calcium fluoride. Further, the heat treatment apparatus had a piping structure capable of introducing a gas-based fluorinating agent and was made of a material which was highly corrosion resistant. Specifically, the external structure was made of stainless steel, and a graphite heater and a graphite container were installed in its interior. The calcium fluoride was placed in this graphite container, and there was a mechanism for rotating this graphite container about the center of the member, and this graphite container was rotated in the range of 1 to 5 rpm.

As for the graphite container, one having a sufficiently large capacity (a capacity 10-fold or more that of the basic material) with respect to the member was used. Approximately 100 g of acid ammonium fluoride was sealed in the graphite container together with the calcium fluoride member. After the interior of the furnace was set in a vacuum state by the vacuum pump, temperature rising was started. The temperature was raised while controlling the pressure so that the in-furnace temperature was kept at a weak positive pressure (2 to 8 kPa), the temperature was then held at 1080° C., and annealing was effected. The heat treatment conditions were set similar to those of Example 1. As a result of this heat treatment, the birefringence in the optical axis direction at the {100} crystal plane of the calcium fluoride member became 2.2 nm/cm. In addition, the birefringence in the lateral direction exhibited a maximum value of 3.4 nm/cm in the <100> direction.

### EXAMPLE 4

A calcium fluoride single-crystal ingot was grown by a method similar to that of Example 1. A plurality of cylindrical members were cut out from this ingot such that the {111} planes became the two upper and lower planes. The birefringence in the {111} crystal plane orientation of the cut-out members was 10 nm/cm or more (before heat treatment). In addition, the birefringence in the lateral direction exhibited a maximum value of 11 nm/cm in the <110> direction. Accordingly, heat treatment was effected at a faster cooling rate than that of the condition in Example 1. As a result of this annealing, the birefringence in the {111} crystal plane orientation after heat treatment of the calcium fluoride member became 1.5 nm/cm. Meanwhile, the birefringence in the lateral direction was 5.9 nm/cm in measurement in an arbitrary direction. However, in the measurement in the <110> direction, the birefringence exhibited a maximum value of 12 nm/cm. Accordingly, since this maximum birefringence value is unsuitable (nonstandard) as an optical member of a lens for a projection optical system of the exposure apparatus, this member was not used as a material for lens forming. In addition, as a result of this example, it was revealed that even if the birefringence in the lateral direction is measured in an arbitrary direction (angle), the material cannot be evaluated sufficiently.

### EXAMPLE 5

A calcium fluoride single-crystal ingot was grown by a method similar to that of Example 1. A plurality of cylindrical members were cut out from this ingot such that the {100} planes became the two upper and lower planes. The birefringence in the {100} crystal plane orientation of the cut-out members was 20 nm/cm or more (before heat treatment). In addition, the birefringence in the lateral direction exhibited a maximum value of 18 nm/cm in the <110> direction. Accordingly, heat treatment was effected at a faster cooling rate than that of the condition in Example 2. As a result of this heat treatment, the birefringence in the {100} crystal plane orientation of the calcium fluoride member became 3.8 nm/cm. Meanwhile, the birefringence in the lateral direction was 7.5 nm/cm in measurement in an arbitrary direction. However, when measurement was made with respect to the <110> direction, the birefringence exhibited a maximum value of 15 nm/cm. Accordingly, since this maximum birefringence value is unsuitable (nonstandard) as an optical member of a lens for a projection optical system of the exposure apparatus, this member was not used as a material for lens forming. In addition, in the same way as Example 4, it was revealed that even if measurement is made in the lateral direction in an arbitrary direction, the material cannot be evaluated sufficiently.

In the present invention, the in-plane (side surface) crystal orientation perpendicular to the optical axis is determined in advance, and the amount of birefringence in a particular crystal plane orientation is measured and managed, thereby making it possible to minimize the effect of the birefringence attributable to the thermal stress on the performance of the optical system.

In accordance with the present invention, it is possible to provide an optical member whose crystal plane orientation other than the optical axis direction is managed, and it becomes possible to ensure desired optical performance. It is possible to provide an exposure apparatus having high resolution by configuring a projection optical system of a projection exposure apparatus employing, as a light source, ultraviolet rays of such as an excimer laser and an F₂ laser by using the optical member thus obtained.

What is claimed is:

1. A method for manufacturing an optical member of a fluoride crystal, comprising:
a growing step of growing an ingot of a fluoride crystal;
a cutting-out step of cutting out from the ingot a cylindrical basic material with two parallel planes which have a certain crystal plane orientation;
an orientation-determining step of determining a crystal orientation of a side surface of the cylindrical basic material;
a birefringence-measuring step of measuring birefringence in a specific crystal axis direction at the side surface determined based on the crystal orientation determined in the orientation-determining step; and
an evaluating step of evaluating the fluoride crystal on the basis of a result of measurement of the birefringence.

2. The method for manufacturing an optical member of a fluoride crystal according to claim 1, wherein, in the orientation-determining step, the crystal orientation at a side surface is determined by measuring the birefringence at the side surface at a plurality of angles.

3. The method for manufacturing an optical member of a fluoride crystal according to claim 1, wherein, in the evaulating step, a determination is made as to whether or not a maximum value of the birefringence in the specific crystal axis direction at the side surface is not more than 10 nm/cm at a measurement wavelength of 633 nm.

4. The method for manufacturing an optical member of a fluoride crystal according to claim 3, wherein when the maximum value of the birefringence in the specific crystal axis direction at the side surface is not more than 10 nm/cm at the measurement wavelength of 633 nm, the basic material is formed into a shape of a predetermined optical member.

5. The method for manufacturing an optical member of a fluoride crystal according to claim 3, wherein the two parallel planes are {111} planes, and the specific crystal direction at the side surface is <110> direction.

6. The method for manufacturing an optical member of a fluoride crystal according to claim 3, wherein the two parallel planes are {100} plane, respectively, and the specific crystal direction at the side surface is <100> direction or <110> direction.

7. An optical member of a fluoride crystal manufactured by the manufacturing method defined in claim 1, wherein a maximum value of the birefringence in a specific crystal axis direction at a side surface of the fluoride crystal, which is shaped in a cylindrical shape with two parallel planes having a specific crystal plane orientation, is not more than 10 nm/cm at a measurement wavelength of 633 nm.

8. The optical member of a fluoride crystal according to claim 7, wherein the specific crystal plane orientation is {111}, and the specific crystal axis direction at the side surface is <110> direction.

9. The optical member of a fluoride crystal according to claim 7, wherein the specific crystal plane orientation is {100}, and the specific crystal axis direction at the side surface is <100> direction or <110> direction.

10. The optical member of a fluoride crystal according to claim 7, wherein the fluoride crystal is a calcium fluoride single crystal.

11. An exposure apparatus including an optical system comprised of the optical member defined in claim 7.
